(19) United States
(12) Patent Application Publication
(10) Pub. No.: US 2014/0214344 A1
(43) Pub. Date: Jul. 31, 2014

(54) ELECTRONIC DEVICE AND ENERGY EFFICIENCY INDICATING METHOD THEREOF

(71) Applicant: HON HAI PRECISION INDUSTRY CO., LTD., New Taipei (TW)

(72) Inventors: YUAN-AN OU, New Taipei (TW); CHIH-CHUN CHANG, New Taipei (TW); CHEN-AN CHIANG, New Taipei (TW); MIN-HUNG HSU, New Taipei (TW)

(73) Assignee: HON HAI PRECISION INDUSTRY CO., LTD., New Taipei (TW)

(21) Appl. No.: 14/016,409

(22) Filed: Sep. 3, 2013

(30) Foreign Application Priority Data
Jan. 31, 2013 (TW) 102103822

(51) Int. Cl. G01R 21/00

(52) U.S. Cl. CPC G01R 21/00
USPC 702/60

(57) ABSTRACT

An electronic device comprises a detecting module, a calculating module, and a display module. The detecting module detects values for parameters of the electronic device. The calculating module calculates current energy efficiency information based on the detected values of the parameters. The displaying module displays a visual interface for indicating the current energy efficiency information of the electronic device.

### BACKGROUND

1. Technical Field

The present disclosure relates to an electronic device and a method for displaying an energy efficiency index.

2. Description of Related Art

An electronic device, such as a TV set, is labeled with an energy label. The energy label indicates a standard energy efficiency index and a standard power of the electronic device. However, the power and the energy efficiency index of the electronic device are affected by a number of operating parameters, such as a working voltage, so that the electronic device does not operate according to the standard energy efficiency index and the standard power. Therefore, the energy label can not accurately indicate the current energy efficiency index and current power of the electronic device.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the electronic device and energy efficiency indicating method thereof. Moreover, in the drawings, like reference numerals designate corresponding parts throughout the several views.

FIG. 1 is a block diagram of an electronic device in accordance with an embodiment.

FIG. 2 is a schematic diagram of a visual interface in accordance with an embodiment.

FIG. 3 is a flowchart of an energy efficiency indicating method in accordance with the embodiment.

FIG. 4 is a flowchart detailing steps of calculating the energy efficiency information based on the detected parameters from the method of FIG. 3, in accordance with the embodiment.

### DETAILED DESCRIPTION

In general, the word “module,” as used herein, refers to logic embodied in hardware or firmware, or to a collection of software instructions, written in a programming language, for example, Java, C, or assembly. One or more software instructions in the modules may be embedded in firmware, such as in an EPROM. Modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage system. Embodiments of the present disclosure will be described with reference to the drawings.

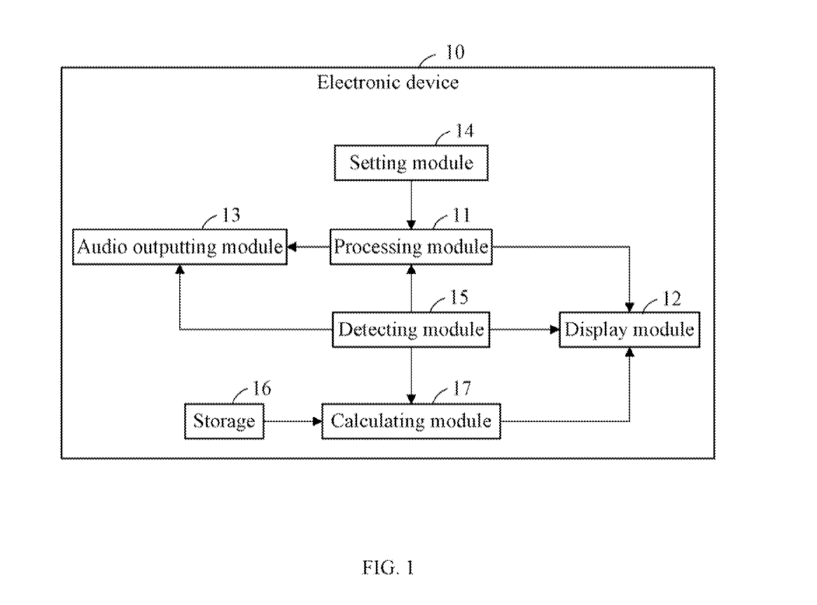

FIG. 1 shows an electronic device 10 of an embodiment. The electronic device 10 displays its actual energy efficiency information when in use. In the embodiment, the electronic device 10 is a TV set. In other embodiments, the electronic device 10 can be a computer or a personal digital assistant (PDA), for example.

The electronic device 10 includes a processing module 11, a display module 12, an audio outputting module 13, a setting module 14, a detecting module 15, a storage 16, and a calculating module 17.

The processing module 11 processes files having a first parameter. In the embodiment, the files are video files, and the first parameter is a format and a resolution of a video file.

The display module 12 displays images having a second parameter. In the embodiment, the display module 12 is a monitor, and the second parameter is the brightness of the display module 12.

The audio outputting module 13 outputs audio having a third parameter. In the embodiment, the third parameter is a volume of the audio.

The setting module 14 adjusts the value of the first parameter, the second parameter, and the third parameter in response to an operation of a user. In the embodiment, the setting module 14 can be keys (not shown) of the electronic device 10, or a remote controller (not shown). In other embodiments, the setting module 14 adjusts the second parameter and the third parameter based on sensing results of different sensors. For example, an optical sensor detects an ambient brightness around the display module 12, and the setting module 14 adjusts the value of the second parameter based on the detected ambient brightness.

The detecting module 15 detects the first parameter, the second parameter, and the third parameter. In the embodiment, the detecting module 15 detects the parameters at a predetermined time frequency while the electronic device 10 is powered on. The predetermined time frequency can be set by the user, or can be predetermined by the electronic device 10. In other embodiments, the detecting module 15 detects the parameters of the electronic device 10 in response to instructions generated by operations of the user.

The storage 16 stores a standard energy efficiency index, a standard total power, a standard value for the first, second, and third parameters, and a plurality of standard powers corresponding to the standard values. Table 1 below shows the relationship between the standard values and the standard powers of the first, second, and third parameters. The standard value for the first parameter is a 480 progressive scan (P) resolution for an analog formal, the standard value for the second parameter is 50 Lumens, and the standard value for the third parameter is 50 decibels (dB). The first standard power is 15 watts (W), the second standard power is 20 W, and the third standard power is 75 W.

TABLE 1

| | First parameter | | |
|---|---|---|---|
| Standard value | Analog formal | Second parameter | Third parameter |
| for parameter | with 480 P | 50 Lumens | 50 dB |
| Standard power | 15 | 20 | 75 |
| (W) | | | |

The storage 16 further stores a plurality of values for the first parameter and a plurality of powers corresponding to the values for the first parameter. Table 2 below shows the relationship between the values for the first parameter and the powers corresponding to the values for the first parameter. The values are resolution for a digital formal or an analog format. The resolutions include 480 P, 720P, 1080P, and 1080 interlaced scan (I).

TABLE 2

| Values | Digital formal | | | Analog formal | | |
|---|---|---|---|---|---|---|
| for first parameter | 480 P | 720 P | 1080 P/I | 480 P | 720 P | 1080 P/I |
| Power (W) | 16 | 17 | 20 | 15 | 16 | 19 |

The calculating module 17 calculates the current total power of the electronic device 10 based on the detected parameters. The calculating module 17 obtains the first current power from the storage 16 based on the detected first parameter. The calculating module 17 calculates the second and the third current power using the following equation:

P_{current}=(P_{standard}/V_{standard})*V_{current}

where Pcurrent is the current power of the parameter, Pstandard is the standard power of the parameter, Vcurrent is the current value of the parameter, and Vstandard is the standard value of the parameter. Then, the calculating module 17 adds the first, second, and third current powers together to obtain a current total power of the electronic device 10.

For example, when the detecting module 15 detects that the first parameter has a 1080 P/I resolution for a digital formal, the detected second parameter has a value of 60 Lumens, and the detected third parameter has a value of 60 dB, the first current power is 20 W, obtained from the storage 16, the second current power is 24 W based on the equation, and the third current power is 90 W based on the equation. The current total power of electronic device 10 is 134 W.

The calculating module 17 further calculates the current energy cost of the current total power based on an electricity cost stored in the storage 16, and calculates a difference between the standard total power and the current total power of the electronic device 10 as a power difference. In the embodiment, the electricity cost is 1 RMB per kW*hour (kWh), so the energy cost is 0.134 RMB/kW*h; the standard total power is 110 W, so the power difference is 24 W.

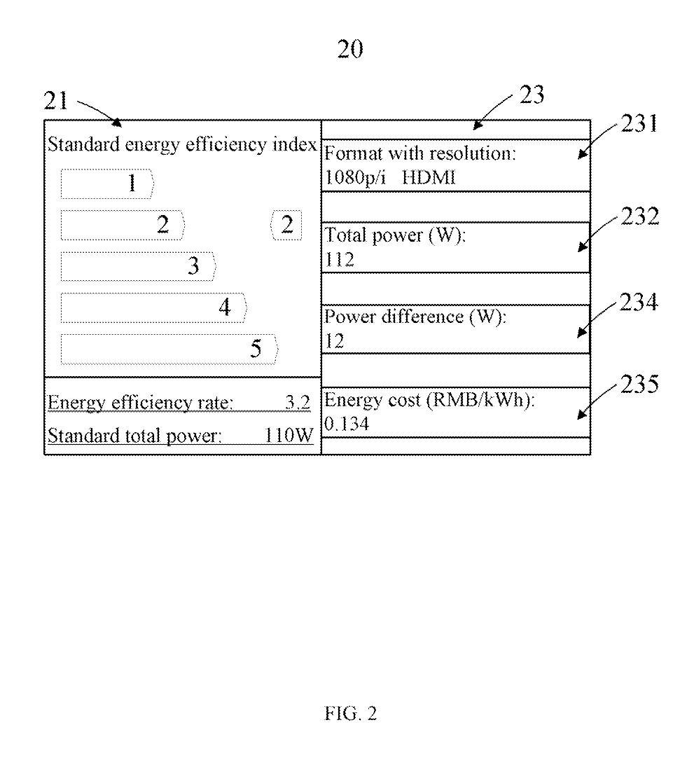

The display module 12 displays a visual interface 20 (as shown in FIG. 2) for indicating the current energy efficiency information of the electronic device 10. The current energy efficiency information includes the resolution with formal for the first parameter, the current total power, the power difference, and the current energy cost. As shown in FIG. 2, the visual interface 20 includes a first display area 21 and a second display area 23. The first display area 21 displays the standard energy efficiency index and the standard power. The second display area 23 displays current energy efficiency information of the electronic device 10. The second display area 23 includes a first row 231, a second row 232, a third row 234, and a fourth row 235. The first row 231 displays the current first parameter. The second row 232 displays the current total power. The third row 234 displays the power difference. The fourth row 235 displays the energy cost. In the embodiment, the visual interface 20 can be changed to delete or add areas or rows, for example.

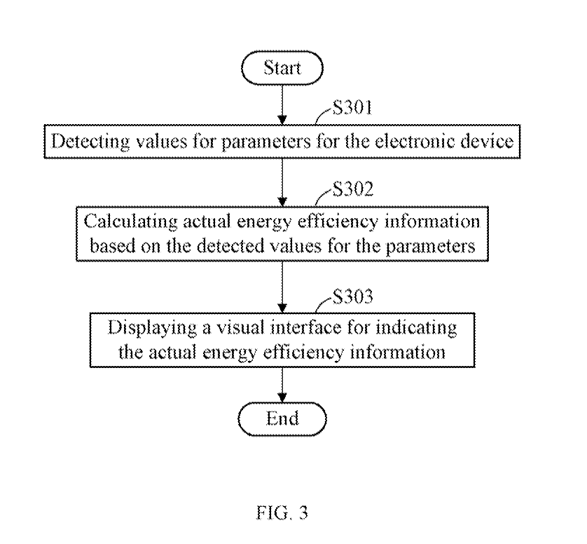

FIG. 3 shows an energy efficiency indicating method of the electronic device 10. The energy efficiency indicating method includes the following steps.

In step S301, the detecting module 15 detects current values for the first, second, and third parameters of the electronic device 10. In the embodiment, the first parameter is the resolution of the video file; the second parameter is the brightness of the display module 12, and the third parameter is the volume of audio outputted by the audio outputting module 13.

In step S302, the calculating module 17 calculates the current energy efficiency information of the electronic device 10 based on the detected parameters. In the embodiment, the energy efficiency information includes a current power, an energy cost, and a power difference.

In step S303, the display module 12 further displays a visual interface 20 for indicating the current energy efficiency information of the electronic device 10. The visual interface 20 includes a first display area 21 and a second display area 23. The first display area 21 displays the standard energy efficiency index and the standard power. The second display area 23 displays current energy efficiency information of the electronic device 10. The second display area 23 includes a first row 231, a second row 232, a third row 234, and a fourth row 235. The first row 231 displays the current first parameter. The second row 232 displays the current total power. The third row 234 displays the power difference. The fourth row 235 displays the energy cost.

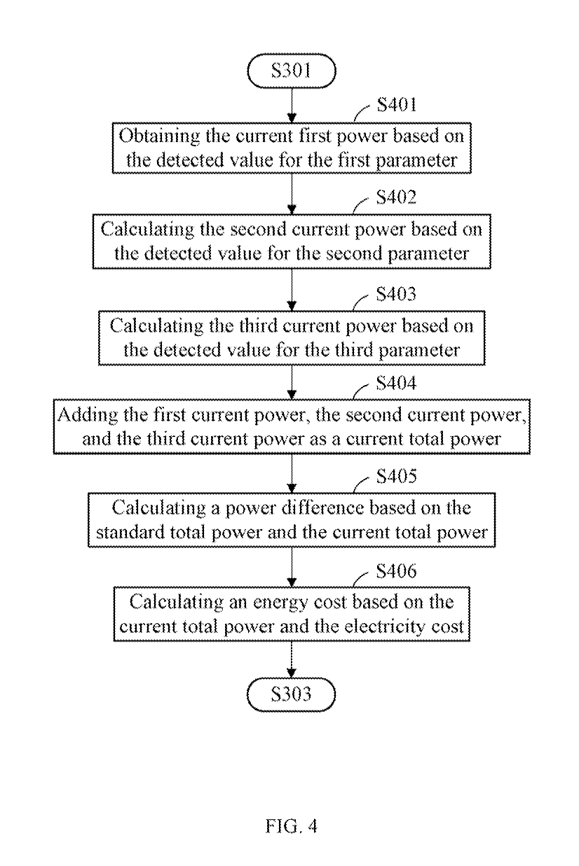

In the embodiment, step S302 further comprises the following steps (shown in FIG. 4).

In step S401, the calculating module 17 obtains the first current power of the detected first parameter. The electronic device 10 stores a plurality of values for the first parameter and a plurality of working powers corresponding to the values for the first parameter.

In step S402, the calculating module 17 calculates the second current power based on the detected second parameter. The electronic device 10 further stores a standard value for the second parameter and a second standard power corresponding to the standard value for the second parameter. The second current power is calculated by the equation P_{current}=(P_{standard}/V_{standard})*V_{current}. In the embodiment, the standard value for the second parameter is 50 Lumens; the second standard power is 20 W.

In step S403, the calculating module 17 calculates the third current power of the detected third parameter. The electronic device 10 further stores a standard value for the third parameter and a third standard power corresponding to the standard value for the third parameter. The third current power is calculated by the equation P_{current}=(P_{standard}/V_{standard})*V_{current}. In the embodiment, the standard power for the third parameter is 50 dB; the third standard power is 75 W.

In step S404, the calculating module 17 adds the first current power, the second current power to the third current power to obtain the current total power.

In step S405, the calculating module 17 calculates a power difference. The electronic device 10 further stores a standard total power. The calculating module 17 calculates a different between the current total power and the standard total power as the power difference.

In step S406, the calculating module 17 calculates an energy cost based on the current total power. The electronic device 10 further stores an electricity cost. The calculating module 17 the energy cost based on the current power and the electricity cost. In the embodiment, the electricity price is 1 RMB per kW*hour.

In use, the electronic device 10 can accurately indicates the actual energy efficiency information to users.

While various exemplary embodiments have been described, the disclosure is not to be limited thereto. Various modifications and similar arrangements (as would be apparent to those skilled in the art) are also intended to be covered. Therefore, the scope of the appended claims should be accorded the broadest interpretation so as to encompass all such modifications and similar arrangements.

What is claimed is:

1. An electronic device comprising:
a detecting module capable of detecting values for parameters of the electronic device;
a calculating module capable of calculating current energy efficiency information based on the detected values of the parameters; and
a display module capable of displaying a visual interface for indicating the current energy efficiency information of the electronic device.

2. The electronic device of claim 1, wherein the current energy efficiency information includes a current total power; the parameters include a first parameter, a second parameter, and a third parameter; the current total power is the sum of a first current power, a second current power, and the third current power which are calculated by the calculating module based on the detected values for the first, second, and third parameter.

3. The electronic device of claim 2, further comprising a processing module and a storage, the processing module processes files having the first parameter; the storage stores a plurality of values for the first parameter and a plurality of power corresponding to the values for the first parameter; the calculating module obtains the power corresponding to the detected value for the first parameter as the first current power.

4. The electronic device of claim 2, wherein the display module further displays images having the second parameter, the second parameter is a brightness of the display module.

5. The electronic device of claim 2, further comprising an audio outputting module, wherein the audio outputting module outputs audio having the third parameter, and the third parameter is the volume of audios.

6. The electronic device of claim 2, further comprising a storage, wherein the storage further stores a standard value for the second and third parameter and two standard powers corresponding to the standard values; the calculating module calculates the second and third current power based on the equation P_{current}=(P_{standard}/V_{standard})*V_{current}.

7. The electronic device of claim 2, further comprising a storage, the energy efficiency information comprising an energy cost; the storage further storing an electricity cost, the calculating module further calculates the energy cost based on the current power and the electricity price.

8. The electronic device of claim 1, further comprising a storage, the storage further storing a standard total power, the energy efficiency information further comprising a power difference; the calculating module further calculating a difference between the standard total power and the current power as the power difference.

9. The electronic device of claim 1, further comprising a storage, the storage further storing a standard energy efficiency index, a standard energy efficiency ratio, and a standard total power which are displayed on the visual interface.

10. An energy efficiency indicating method for an electronic device, the energy efficiency indicating method comprising:
detecting values of parameters for the electronic device;
calculating energy efficiency information based on the detected values of the parameters; and
displaying a visual interface for indicating the calculated energy efficiency information.

11. The method of claim 10, wherein the parameters include a first parameter, a second parameter, and a third parameter, the step of calculating energy efficiency information based on the detected values for the parameters further comprising:
obtaining the corresponding power corresponding to the detected value for the first parameter as a first current power;
calculating a second current power based on the detected second parameter; and
calculating a third current power based on the detected third parameter; and
adding the first current power, the second current power, and the third current power together as a current total power.

12. The method of claim 11, wherein the electronic device stores a plurality of values for the first parameter and a plurality of powers corresponding to the values for the first parameter.

13. The method of claim 11, wherein the electronic device further stores a standard value for the second and third parameter and two standard powers corresponding to the standard value for the second and third parameter; the second and the third current power is achieved by the equation P_{current}=(P_{standard}/V_{standard})*V_{current}.

14. The method of claim 11, wherein the electronic device further stores a standard total power, after the step of adding the first current power, the second current power, and the third current power as an current total power further comprising:
calculating a difference between the standard total power and the current total power as a power difference.

15. The method of claim 11, wherein the electronic device further stores an electricity cost, after the step of adding the first current power, the second current power, and the third current power as an current total power further comprising:
calculating an energy cost of the current total power based on the electricity cost.

16. The method of claim 10, wherein the visual interface further display a standard energy efficiency index, a standard energy efficiency ratio, and a standard total power.
